(19) United States
(12) Patent Application Publication
(10) Pub. No.: US 2026/0342310 A1
(43) Pub. Date: Oct. 29, 2026

(54) STRESS ISOLATED QUARTZ CRYSTAL RESONATING ELEMENT AND QUARTZ CRYSTAL RESONATOR

(71) Applicant: RAKON LIMITED, Auckland (NZ)

(72) Inventors: Ryan John BARRON, Auckland (NZ); Michael Shawn MCILROY, Auckland (NZ); Wenhua ZHAO, Auckland (NZ)

(21) Appl. No.: 19/099,013

(22) PCT Filed: Jul. 25, 2023
(86) PCT No.: PCT/IB2023/057549

§ 371 Date: Jan. 27, 2025

(30) Foreign Application Priority Data
Jul. 26, 2022 (NZ) 790650

(51) Int. Cl. H03H 9/17; H03B 5/32; H03H 9/13

(52) U.S. Cl. CPC H03H 9/17; H03B 5/32; H03H 9/13

(57) ABSTRACT

The present invention offers novel ways of achieving high degree of mechanical stress isolation and high accuracy of temperature sensing in quartz crystal resonators.

### FIELD OF THE INVENTION

The present invention relates to quartz crystal frequency control devices used in a variety of applications where accurate and stable frequency reference and/or timing signals are required. More specifically, the present invention relates to quartz crystal resonators with reduced sensitivity to mechanically and thermally induced stresses, and quartz crystal oscillators comprising such resonators.

### BACKGROUND OF THE INVENTION

Quartz crystal resonators are key components in frequency control devices that are capable of generating electronic signals characterized by high frequency stability.

Resonators such as, for example, a rectangular (“strip”) quartz crystal resonator shown in FIG. 1, comprise a quartz crystal piezoelectric resonating element (1) mounted onto a substrate (2) and operating in a hermetically sealed environment. The area (3) of piezoelectric material between, and in close vicinity of, the electrodes is referred to as the active vibration area or active vibration region, as that is where most of the vibration displacement takes place during normal operation of the resonating element.

Quartz crystal resonators can be adversely affected by mechanical stresses. The latter can be induced either mechanically, such as in cases of mechanical acceleration, shock, or vibration applied to the resonator, or thermally, when the resonator's ambient temperature changes. Mechanically or thermally induced stresses cause undesirable resonant frequency changes, resulting in compromised frequency stability of frequency control devices comprising the quartz crystal resonators, and adversely affecting a number of performance parameters such as thermal hysteresis, sensitivity to acceleration, long-term frequency stability, reflow shift, frequency wander, mechanical shock response, and others.

Several approaches have been known to reduce the sensitivity of resonators to mechanically and thermally induced stresses.

The use of cantilever mounting of resonating elements is one such approach. Cantilever-mounted resonating elements are often mounted onto a substrate using softer, less rigid mounting materials, which helps to further reduce the effects of mechanically or thermally induced stresses.

Also known are resonating elements with stress isolating structures, such as, for example, those disclosed in U.S. Pat. No. 8,912,711 and U.S. Pat. No. 9,991,863 where two “tethers” are arranged to extend from the vicinity of the active vibration region. The two “tethers” accommodate the two electrical signal lines of the resonating element and terminate in two separate areas of piezoelectric material intended for mounting of the resonating element. Resonating elements of this type are mounted using at least two mounting points located in two separate locations of the resonating element's mounting area.

The present invention advances the current state of the art by offering quartz crystal resonating elements and resonators with novel stress isolating structures that result in reduced sensitivity to mechanically or thermally induced stresses and improved resonator performance.

Another aspect of the present invention is that the stress isolating structures of the resonating elements of the present invention also facilitate accurate sensing of the resonating elements' temperature, which is advantageous in improving the performance of frequency control devices utilizing resonators' temperature sensing, such as, for example, Temperature Compensated Crystal Oscillators (TCXO), Oven-Controlled Crystal Oscillators (OCXO), and others.

### SUMMARY OF THE INVENTION

The term “comprising”, as used in this specification and claims, means “consisting at least in part of”. When interpreting each statement in this specification and claims that includes the term “comprising”, features other than that or those prefaced by the term may also be present. Related terms such as “comprise” and “comprises” are to be interpreted in the same manner.

One of the main aspects of the present invention is that the area of the resonating element intended for mounting of the resonating element (“mounting area”) comprises a single, undivided, or substantially undivided area that makes it possible to cantilever mount the resonating element using either a single mounting point (“single-point mounting”), or more than one mounting points in such a way whereby all of the mounting points and the said single, undivided area are overlapping, and that the active vibration area of the resonator is semi-separated from the mounting area by means of one or more slots, or voids, arranged in the structure of the resonating element. In embodiments wherein the mounting points are located on the same side of the resonating element, this aspect of the present invention can be described by stating that the mounting area comprises a single, undivided or substantially undivided area that makes it possible to cantilever mount the resonating element by means of one or more mounting points that are overlain by the said single, undivided or substantially undivided area, and that the active vibration area of the resonator is semi-separated from the mounting area by means of one or more slots, or voids, arranged in the structure of the resonator.

It could be observed that since the said single, undivided, or at least substantially undivided, area and the mounting points overlap each other, the mounting points can be said to be linked by the body of the resonating element entirely within the mounting area.

Another aspect of the present invention is that the aforementioned single, undivided or substantially undivided mounting area can be advantageously used as a location for placement of a temperature sensing element-this allows attaining close proximity of the temperature sensing element to the resonating element and, consequently, higher accuracy of resonating element's temperature sensing, while at the same time minimizing any adverse effects that the temperature sensing element might have on the active vibration area of the resonator.

### BRIEF DESCRIPTION OF THE DRAWINGS

The invention is further described with reference to the accompanying figures in which,

FIG. 1 shows a prior art “strip” resonator, with a resonating element that is two-point mounted onto a substrate of a resonator package.

FIGS. 2a to 2e show several embodiments of resonating elements incorporating stress isolation structures of the present invention.

FIG. 3 shows a resonating element of the present invention that is single-point cantilever mounted onto, and electrically connected to, a substrate of a resonator package. FIG. 4 shows a resonating element of the present invention with a temperature sensing element installed in the stress isolated mounting area, the resonating element single-point cantilever mounted onto, and connected to, a substrate of the resonator package.

FIG. 5 presents a comparison of resonating element's temperature sensing for three different positions of temperature sensing element.

FIG. 6 shows the distribution of thermally induced stress in a prior art resonating element.

FIG. 7 shows the distribution of thermally induced stress in a resonating element of the present invention.

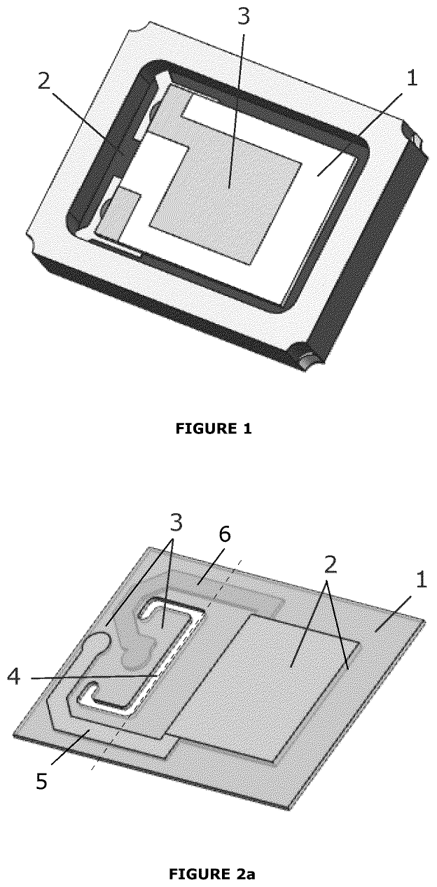

### DETAILED DESCRIPTION OF THE INVENTION

Without limiting the scope of the present invention, the latter is illustrated herein by the following specific embodiments of resonating elements and resonators with stress isolating structures of the present invention.

In all of the embodiments described below, each of the resonating elements comprises an active vibration area, which is defined by the location of two electrodes that are disposed onto, or arranged to be in close vicinity to, the opposing surfaces of the resonating element, and a mounting area comprising an undivided, or at least substantially undivided, area that can be used for single-point or multiple-point mounting of the resonating element and that is semi-separated from the active vibration area by means of at least one void, or slot, arranged in the resonating element's structure.

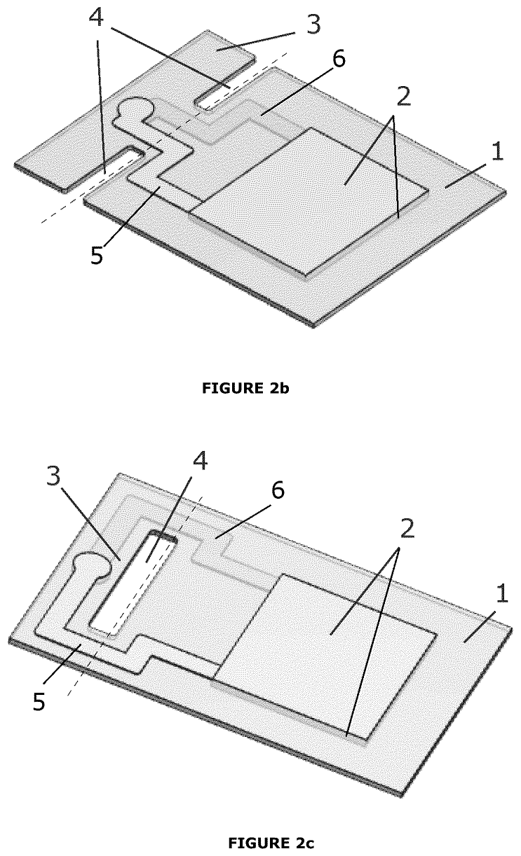

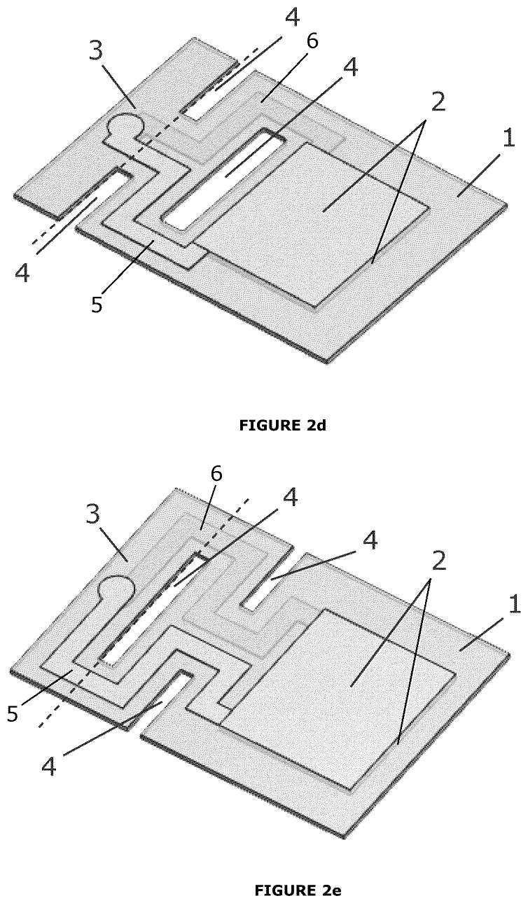

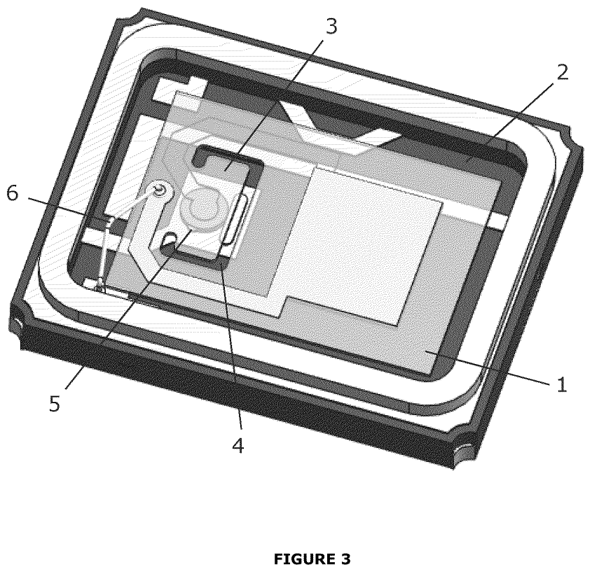

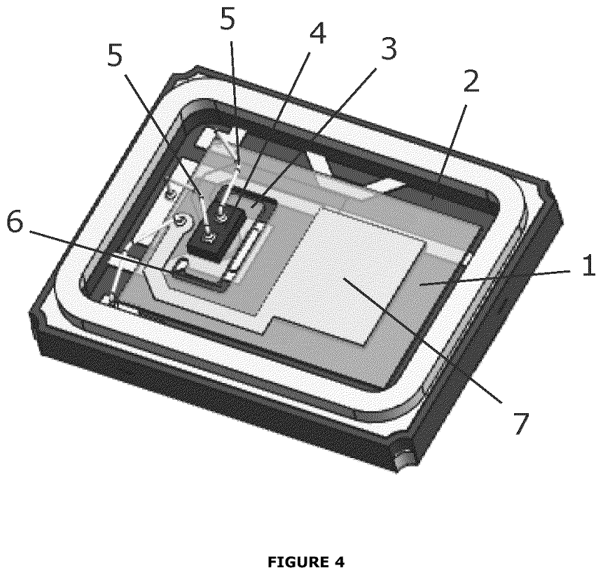

One of the embodiments of a resonating element with a stress isolation structure of the present invention is shown in FIG. 2a. The resonating element (1) comprises two electrodes (2) that are disposed on opposing surfaces of the resonating element (1) and thus define the location of the active vibration region (located to the right hand side from the dashed line in FIG. 2a), and a mounting area (located to the left of the dashed line) that comprises an integrated, single, undivided area (3) that is semi-separated from the active vibration region by the void or slot (4). Both of the two signal lines (5) and (6) running from the two electrodes (2) are terminated in the said area (3).

FIG. 2b shows yet another embodiment of the present invention. The two electrodes (2) disposed on the two opposing sides of the resonating element (1) define the location of the active vibration region, and the latter is stress-isolated from the single, undivided mounting area (3) (located to the left of the dashed line in FIG. 2b) by means of two voids/slots (4). Both of the two signal lines (5) and (6) running from the two electrodes (2) are terminated in the said area (3).

In yet another embodiment of the present invention, shown in FIG. 2c, the active vibration region of the resonating element (1) is defined by the position of two electrodes (2) disposed on the opposing surfaces of the resonating element (1) and stress isolated from the mounting area (3) (located to the left of the dashed line in FIG. 2c) by means of a slot/void (4). Both of the two signal lines (5) and (6) running from the electrodes (2) are terminated in the said area (3).

FIG. 2d illustrates yet another embodiment of the present invention. The two electrodes (2) disposed on the two opposing sides of the resonating element (1) define the location of the active vibration region, and the undivided mounting area (3) (located to the left of the dashed line in FIG. 2d) is semi-separated from the active region by means of three voids/slots (4). Both of the two signal lines (5) and (6) running from the electrodes (2) are terminated in the said area (3).

FIG. 2e shows yet another embodiment of the present invention. The two electrodes (2) disposed on the two opposing sides of the resonating element (1) define the location of the active vibration region, and the mounting area (3) (located to the left of the dashed line in FIG. 2e) is semi-separated from the active region by means of three voids/slots (4). Both of the two signal lines (5) and (6) running from the electrodes (2) are terminated in the said area (3).

Each of the resonating elements shown in FIGS. 2a to 2e can be mounted onto a substrate using one or more mounting points located in the undivided, or substantially undivided, area (3), in which case the said one or more mounting points and the said undivided, or substantially undivided, area (3) will be overlapping each other.

An example of single-point mounting is shown in FIG. 3. The single, undivided mounting area (3), that is semi-separated from the active vibration region of the resonating element (1) by means of slot (4), can be used to arrange single-point cantilever mounting of the resonating element (1) onto a substrate using any of presently known mounting materials: for example, conductive glue (5) can be used to mechanically mount the resonating element (1) to the substrate (2) and at the same time to ensure the electrical connection of one of the electrodes (i.e., the electrode facing the substrate) to the conductive pad on the substrate (2). The second electrode can be electrically connected to the substrate using wire bonding (6) to a conductive pad on the substrate. More than one mounting points, located under, and overlapping with, the area (3) can be used to mount the resonating element (1) to substrate (2).

FIG. 4 shows the structure of a resonator comprising a resonating element (1) of the present invention, single-point mounted onto the surface of the substrate (2) of the resonator's package, with a temperature sensing element (4) installed in the semi-separated, and thus stress-isolated from the active vibration region (7), mounting area (3). The active vibration region (7) is semi-separated from the mounting area (3) and thus stress isolated by means of the slot/void (6). The temperature sensing element (4) is connected to conductive pads on the substrate (2) by means of two wire bonds (5). Although the temperature sensing element (4) is installed onto the surface of the resonating element, it's presence does not detrimentally affect the vibrations in the active region (7) due to the stress isolation of the active region (7) from mounting area (3) where the temperature sensing element is installed. This allows closer, and therefore more accurate, sensing of the resonating element's temperature without causing unwanted degradation of the resonating element's operation.

Referring back to FIG. 3, it should be noted that in cases when the resonating element of the present invention is used as part of a resonator without the temperature sensing element installed in the mounting area, the terminal point of the upper electrode's signal line where one end of the wire bond (6) is located can be moved to overlap with the mounting point (5) in order to improve manufacturability of the resonator assembly by creating support during the wire bonding process.

### Structural Advantages

The stress isolation structures of the present invention, comprising a single, substantially undivided mounting area suitable for single-point mounting of the resonating element to a substrate, have a number of structural advantages compared to those of prior art. In particular, compared to stress isolation structures comprising two separate “tethers”, the structures of the present invention (a) are more mechanically rigid, and (b) eliminate the need for any means of bringing one of the signal lines over to the opposing side of the resonating element, such as, for example, plated vias through the resonating element or edge-plated conductive connections.

### Performance Advantages

Compared to prior art resonators with resonating elements comprising two “tethers”, resonators with resonating elements comprising stress isolating structures of the present invention exhibit a number of performance advantages.

Modelling shows that a cantilever-mounted stress-isolated resonator of prior art exhibits sensitivity to mechanical acceleration in the longitudinal direction of about 0.2863 ppb/g, whereas a resonator with a resonating element shown in FIG. 2a exhibits sensitivity to acceleration in the longitudinal direction of about 0.2005 ppb/g, which is an approximately 30% improvement (reduction) in acceleration sensitivity.

In the direction of the resonating elements' thickness, the magnitudes of sensitivity to mechanical acceleration exhibited by prior art resonators and the resonators of the present invention are 0.0195 ppb/g and 0.0077 ppb/g correspondingly, which is an improvement (reduction) of approximately 60%.

When subjected to an ambient temperature shift from 95 °C to 130 °C, the magnitudes of strain-induced resonant frequency shift in a prior art resonator and in a resonator of the present invention are 558.36 ppb and 42.4040 ppb correspondingly, which is more than an order of magnitude (i.e., more than 10 times) improvement (reduction).

When subjected to a cyclical ambient temperature change whereby the ambient temperature is changed from +25 °C to +85 °C, then reduced to −40 °C, and then returned back to +25 °C, the maximum resonant frequency difference at an ambient temperature point when temperature is moving in opposite directions (“frequency hysteresis”) can be as high as 20ppb in prior art resonators, whereas the frequency hysteresis exhibited by resonators of the present invention is about 10 ppb, which is a 2-fold improvement (reduction).

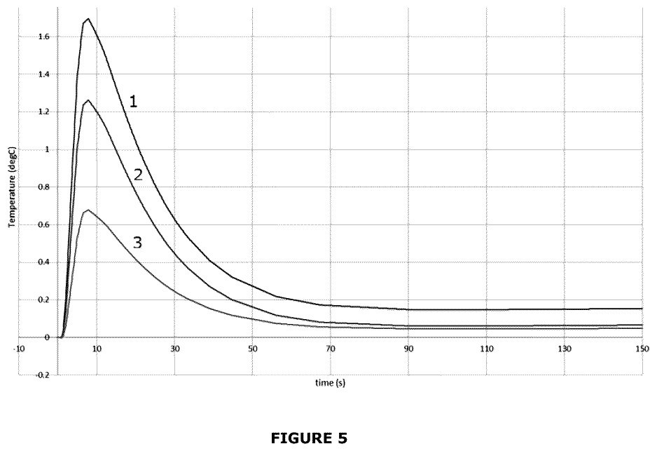

Accurate sensing of the resonating element's temperature is a critical factor in achieving high frequency stability in frequency control devices such as Temperature Compensated Crystal Oscillators (TCXO), Oven-Controlled Crystal Oscillators (OCXO), and others. Positioning the temperature sensing element directly onto the surface of the resonating element, as opposed to in a location that is close to the resonating element, renders the highest temperature sensing accuracy, as illustrated in FIG. 5. Lines 1, 2, and 3 represent the modelled difference between the temperature of the active region of a rectangular “strip” resonating element and the temperature sensed by a temperature sensing element when the resonator is subjected to a rapid temperature change from 0 °C to +85 °C, for each of the following three positions of the temperature sensing element: on the substrate and next to the resonating element (line 1), on the substrate and under the active region of the resonating element (line 2), and directly on the surface of the resonating element (line 3).

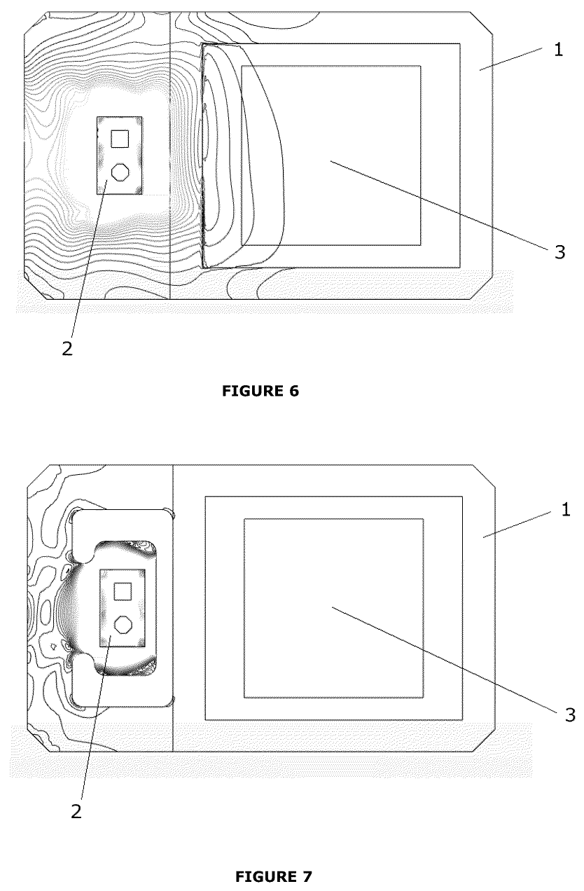

As can be deduced from FIG. 5, positioning the temperature sensing element directly on the surface of the resonating element renders the most accurate temperature sensing. However, as has already been mentioned herein, positioning of the temperature sensing element on the resonating element's surface causes detrimental effects in the critically important active vibration region of the resonating element. Utilizing resonating elements of the present invention, with temperature sensing elements installed in the stress-isolated mounting area, presents an advantageous novel solution whereby it becomes possible to accurately sense the temperature of the resonating element and at the same time avoid the undesirable stress-related effects in the active vibration region. FIGS. 6 and 7 serve to illustrate the aforementioned solution.

FIG. 6 shows stress distribution in a prior art resonating element (1) with a temperature sensing element (2) installed directly onto the surface of the prior art resonating element (1), when the resonator comprising the resonating element (1) is subjected to a rapid temperature change from 0 °C to +85 °C. There is a considerable propagation of stress (indicated by the isostress lines) into the active vibration region (3), as indicated by the position of isostress lines in FIG. 6. The value of calculated von Mises stress in the active vibration region (3) is 314.37 kPa.

FIG. 7 shows stress distribution in a resonating element of the present invention (1) with a temperature sensing element (2) installed directly onto the surface of the resonating element of the present invention (1) when the resonator comprising the resonating element (1) is subjected to a similar temperature change from 0 °C to +85 °C. As shown in FIG. 7 by the position of the isostress lines, the active vibration region (3) is essentially isolated from the thermally induced stress. The value of calculated von Mises stress in the active vibration region (3) in this case is 16.59 kPa, which is about 19 times lower than in the prior art case illustrated in FIG. 6, and about 6 times lower than in a prior art resonator even without the temperature sensing element (von Mises stress value: 100.02 kPa).

### Applications

The stress-isolated resonating elements and resonators implemented as per the present invention can be advantageously used in a variety of electronic devices and apparatus. Such devices include, but are not limited to, quartz crystal oscillators (XO), including Temperature Compensated Crystal Oscillators (TCXO) and Oven-Controlled Crystal Oscillators (OCXO). A variety of electronic apparatus will benefit from using the resonating elements and resonators of the present invention, as well as devices incorporating the resonating elements and resonators of the present invention; such apparatus include, but are not limited to, portable and stationary telecommunication equipment, high speed networking equipment, radio communication equipment, and navigation equipment.

1. A quartz crystal resonating element comprising:
a mounting area, and
an active vibration area,
wherein the mounting area comprises an undivided area suitable for cantilever mounting of the resonating element through one or more mounting points in such a way that the one or more mounting points and the said undivided area overlap each other, and
wherein the active vibration area is semi-separated from the undivided area suitable for cantilever mounting by means of at least one slot or void arranged in the resonating element, and
wherein a temperature sensing element is attached onto the undivided area.

2. A resonator comprising a quartz crystal resonating element according to claim 1.

3. A resonator according to claim 24 wherein the quartz crystal resonating element is single-point cantilever mounted onto he substrate.

4. A resonator according to claim 24 wherein the quartz crystal resonating element is electrically connected to a conductive pad on the surface of the substrate by means of a wire bond connecting the quartz crystal resonating element and the conductive pad.

5. (canceled)

6. (canceled)

7. A resonator according to claim 24 wherein the temperature sensing element is electrically connected to at least one conductive pad on the surface of the substrate by at least one wire bond connection.

8. (canceled)

9. An electronic device comprising a quartz crystal resonating element according to claim 1.

10. (canceled)

11. An electronic device according to claim 9, wherein the electronic device is one or more of
a quartz crystal oscillator.
a Temperature Compensated Crystal Oscillator, and
an Oven-Control ed Crystal Oscillator.

12. (canceled)

13. (canceled)

14. (canceled)

15. (canceled)

16. (canceled)

17. A quartz crystal resonating element according to claim 1 wherein the active vibration area is defined by the location of two electrodes on the opposing surfaces of the resonating element.

18. A quartz crystal resonating element according to claim 1 comprising two signal lines, each signal line extending from one of the electrodes to the undivided area.

19. A quartz crystal resonating element according to claim 1 comprising a single slot or void.

20. A quartz crystal resonating element according to claim 19 wherein the slot or void is generally C-shaped.

21. A quartz crystal resonating element according to claim 19 wherein the slot or void comprises a first section extending transversely and two side sections which extend longitudinally at either end of the transversely extending section.

22. A quartz crystal resonating element according to claim 21 wherein the slot or void comprises a return section at the end of each side section, each return section extending transversely from the end of each side section toward a central axis bisecting the first section.

23. A quartz crystal resonating element according to claim 1 wherein the undivided area forms a peninsula extending toward the active vibration area and is separated from the active vibration area by the slot or void.

24. A resonator according to claim 2, wherein the quartz crystal resonating element is mounted onto a substrate.

25. A quartz crystal resonating element comprising:
a mounting area,
an active vibration area, and
wherein the mounting area comprises an undivided area suitable for cantilever mounting of the resonating element through one or more mounting points in such a way that the one or more mounting points and the said undivided area overlap each other,
wherein the active vibration area is semi-separated from the undivided area suitable for cantilever mounting by means of one C-shaped slot or void arranged in the resonating element.

26. A quartz crystal resonant element according to claim 25 wherein the slot or void comprises a first section extending transversely and two side sections which extend longitudinally at either end of the transversely extending section.

27. A quartz crystal resonant element according to claim 25 comprising a mounting point on the lower surface of the mounting area, the mounting point overlapping with a terminal point of an upper electrode signal line.

28. A quartz crystal resonant element according to claim 25 wherein the undivided area forms a peninsula extending toward the active vibration area and is separated from the active vibration area by the slot or void.

29. A quartz crystal resonating element comprising:
a mounting area,
an active vibration area, and
wherein the mounting area comprises an undivided area suitable for cantilever mounting of the resonating element through one or more mounting points in such a way that the one or more mounting points and the said undivided area overlap each other, and
wherein the active vibration area is semi-separated from the undivided area suitable for cantilever mounting by means of a slot or void arranged in the resonating element, the undivided area forming a peninsula extending toward the active vibration area and separated from the active vibration area by the slot or void.
